(19) United States
(12) Patent Application Publication
(10) Pub. No.: US 2020/0344873 A1
(43) Pub. Date: Oct. 29, 2020

(54) PRINTED CIRCUIT BOARD (PCB) AND DISPLAY DEVICE

(71) Applicant: Shenzhen China Star Optoelectronics Technology Co., Ltd., Shenzhen (CN)

(72) Inventor: Jianfeng XIAO, Shenzhen (CN)

(21) Appl. No.: 16/607,134

(22) PCT Filed: Jul. 3, 2019
(86) PCT No.: PCT/CN2019/094623

§ 371 Date: Oct. 22, 2019

(30) Foreign Application Priority Data
Apr. 29, 2019 (CN) 201910356989.2

(51) Int. Cl. H05K 1/02; H05K 1/09

(52) U.S. Cl. CPC H05K 1/0228; H05K 1/09; H05K 2201/09227; H05K 2201/093; H05K 2201/10136

(57) ABSTRACT

A printed circuit board (PCB) and a display device are provided. The PCB includes a first trace layer, a reference ground layer disposed above and insulated from the first trace layer, and a third trace layer disposed above and insulated from the reference round layer. The first trace layer includes a gate over array (GOA) signal trace group, a data signal trace group, and a signal isolating trace disposed on the same plane, and the GOA signal trace group and the data signal trace group are disposed on opposite sides of the signal isolating trace, thereby avoiding signal interference between the trace layers in the printed circuit board, and effectively ensuring stable operation of the display device.

### FIELD OF INVENTION

The present invention relates to display technologies, and more particularly to a printed circuit board (PCB) and a display device.

### BACKGROUND

With development of display technology, flat display devices, such as liquid crystal displays (LCDs), are widely used in mobile phones, televisions, personal digital assistants (PDAs), digital cameras, notebook computers, desktop computers and other consumer electronic products and have become the mainstream in display devices due to their good image quality, power savings, thin body and wide applications.

Most of the LCD devices on the market are backlight type LCD devices, which comprise a liquid crystal panel and a backlight module. Working principle of the liquid crystal panel is to place liquid crystal molecules in two parallel glass substrates and control the liquid crystal molecules to change direction via a supplied power or not and refract light of the backlight module to form an image.

Gate Driver on Array (GOA) technology is an array substrate row driving technology, which uses a thin film transistor (TFT) liquid crystal display array process to fabricate a gate scan driving circuit on a thin film transistor array substrate to realize progressive scanning. The driving method has the advantages of reducing production cost and realizing the narrow frame design of the panel, and it can used for various displays. Conventionally, a GOA circuit control signal is generally input to the GOA circuit to implement a progressive scan function of the GOA circuit. The GOA circuit control signal comprises a start signal and a plurality of clock signals, and the initial signal and the clock signal are pulse signals. The high and low potentials of the initial signal and the clock signal are generally 30V and −10V.

In current LCD display devices, a plurality of chip on film (COF) elements are bonded to a liquid crystal panel, and two X boards are then bonded to the COF elements. The driving signal passes through the X boards to the COF elements to preform driving of the liquid crystal panel. Currently, the X board is mostly a printed circuit board (PCB), which comprises a plurality of layers of interconnected trace layers. In the liquid crystal display device using the GOA technology, the GOA circuit control signal is also generally supplied from the X board to the COF elements and then to the GOA circuit in the liquid crystal panel. Referring to FIG. 1, a conventional printed circuit board functioning as an X board comprises a first trace layer 100, a reference ground layer 200, a second trace layer 300, and a third trace layer 400 which are sequentially disposed. The first trace layer 100 is used to transmit data signals, the reference ground layer 200 is used to couple the reference ground potential, the second trace layer 300 is used to supply positive voltage and the GOA circuit control signal, and the third trace layer 400 is used to form electronic components and output pins. In this architecture, since the GOA circuit control signals transmitted by the second wiring layer 300 are all pulse signals, the switching between the high and low levels is continuously performed, thereby causing interferences to signal in the adjacent trace layers during the level switching. The trace layers adjacent to the second trace layer 300 are the reference ground layer 200 and the third trace layer 400. The reference ground layer 200 is not affected by the level switching of the GOA signal trace, and the reference ground layer 200 will not be affected by the level switching of the GOA signal trace, but the driving signals transmitted by the third trace layer 400 to the COF elements are interfered by the control signal of the GOA circuit, resulting in unstable operation or malfunction of the liquid crystal display device, which affects quality of the panel.

### SUMMARY

An object of the present invention to provide a printed circuit board (PCB) capable of avoiding signal interference between the trace layers in the PCB, and it can be used in a display device to effectively ensure stable operation of the display device.

Another object of the present invention is to provide a display device capable of avoiding signal interference between trace layers in a printed circuit board, thereby effectively ensuring stable operation of the display device.

To achieve the above object, the present invention first provides a printed circuit board comprising a first trace layer, a reference ground layer disposed above and insulated from the first trace layer, and a third trace layer disposed above and insulated from the reference round layer.

The first trace layer comprises a gate over array (GOA) signal trace group, a data signal trace group, and a signal isolating trace disposed in the same plane, and the GOA signal trace group and the data signal trace group are disposed on opposite sides of the signal isolating trace.

The signal isolating trace is coupled to a reference ground potential.

A width of the signal isolating trace is greater than or equal 0.5 mm.

The signal isolating trace is made of metal material.

The signal isolating trace is made of copper.

The PCB further comprises a second trace layer disposed between and isolated from the reference ground layer and the third trace layer, and the second trace layer is configured to supply positive voltage.

The GOA signal trace group is configurated to transmit GOA circuit control signals that are pulse signals.

The GOA circuit control signals comprise a start signal and at least one clock signal.

The reference ground layer is coupled to a reference ground potential.

The present invention further provides a display device comprising the above-mentioned PCB.

### Advantageous Effects

A printed circuit board of the present application comprises a first trace layer, a reference ground layer disposed above and insulated from the first trace layer, and a third trace layer disposed above and insulated from the reference round layer. The first trace layer comprises a gate over array (GOA) signal trace group, a data signal trace group, and a signal isolating trace disposed in the same plane, and the GOA signal trace group and the data signal trace group are disposed on opposite sides of the signal isolating trace.

Therefore, a signal interference between the trace layers in the PCB can be avoided, and the stable operation of the display device is effectively ensured. The display device of the present invention can avoid signal interference between the trace layers in the PCB, and effectively ensures stable operation of the display device.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a schematic cross-sectional view of a structure of a conventional printed circuit board called as an X board.

FIG. 2 is a schematic cross-sectional view of a structure of a printed circuit board of the present invention.

FIG. 3 is a partial schematic top view showing a boundary between a GOA signal trace group, a signal isolation trace, and a data signal trace group in a first trace layer of the printed circuit board of the present invention.

FIG. 4 is a schematic structural view of a display device of the present invention.

FIG. 5 is a schematic view showing the connection of a printed circuit board and a flip chip film in the display device of the present invention.

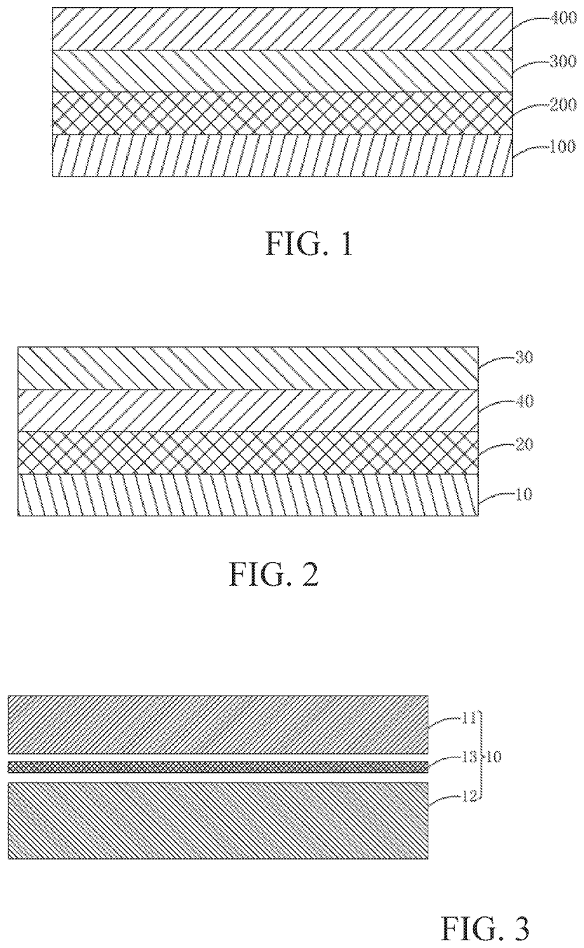

### DETAILED DESCRIPTION

The specific structural and functional details disclosed are merely representative and are for the purpose of describing exemplary embodiments of the invention.

Referring to FIG. 2, the printed circuit board (PCB) of the present invention comprises a first trace layer 10, a reference ground layer 20 disposed above and insulated from the first trace layer 10, and a third trace layer 30 disposed above and insulated from the reference round layer. Referring to FIG. 3, the first trace layer 10 comprises a gate over array (GOA) signal trace group 11, a data signal trace group 12, and a signal isolating trace 13 disposed in the same plane. The GOA signal trace group 11 and the data signal trace group 12 are disposed on opposite sides of the signal isolating trace 13.

More specifically, the signal isolating trace 20 is coupled to a reference ground potential. The third trace layer 30 is used to form electronic components and output pins, and driving signals are transmitted to chip on film (COF) elements via electrically connecting the chip in films in the display device through the output pins. The data signals trace group 12 is configured to transmit data signals, and the GOA signal trace group 11 is configured to transmit GOA circuit control signals, and the GOA circuit control signals are pulse signals. The high potential of the GOA circuit control signals is about 30V, and the low potential of the GOA circuit control signals is about −10V.

More specifically, the GOA circuit control signals comprise a start signal and at least one clock signal.

More specifically, the signal isolating trace 13 is coupled to a reference ground potential.

More specifically, a width of the signal isolating trace 13 is greater than or equal to 0.5 mm.

More specifically, the signal isolating trace 13 is made of metal material. Preferably, the signal isolating trace 13 is made of copper.

More specifically, please referring to FIG. 2, the PCB further comprises a second trace layer 20 disposed between and isolated from the reference ground layer 20 and the third trace layer 30, and the second trace layer 40 is configured to supply positive voltage.

It is noted that, in combination with FIG. 5, while the PCB of the first embodiment of the present invention is used in a display device, it functions as an X board of the display device to electrically connect and transmit driving signals to the COF elements 201 of the display device. In the present application, the first wiring layer 10 comprising the GOA signal trace group 11, the data signal trace group 12, and the signal isolation trace 13 in the same plane is disposed, and the GOA signal trace group 11 and the data signal trace group 12 are respectively located on both sides of the signal isolation trace 13. A reference ground layer 20 is disposed above the first trace layer 10 and a third trace layer 30 is disposed above the reference ground layer 20. The third trace layer 30 is not adjacent to the GOA signal trace group 11 transmitting the GOA circuit control signals, so that the transmitted driving signals are not interfered by the GOA circuit control signals. Although the reference ground layer 20 is adjacent to the first trace layer 10, since the reference ground layer 20 is coupled to the reference ground potential, its potential is not affected by the transmitted driving signals of the GOA signal trace group 11. Furthermore, since the first trace layer 10 comprises the GOA signal trace group 11, the data signal trace group 12 and the signal isolation trace 13 disposed on the same plane, and the GOA signal trace group 11 and data signal trace group 12 are respectively on both sides of the signal isolation trace 13, the GOA circuit control signals transmitted by the GOA signal trace group 11 can be prevented from interfering with the data signal transmitted by the data signal trace group 12, thereby avoiding signal interferences in each of the trace layers in the printed circuit board and effectively ensures the stable operation of the display device.

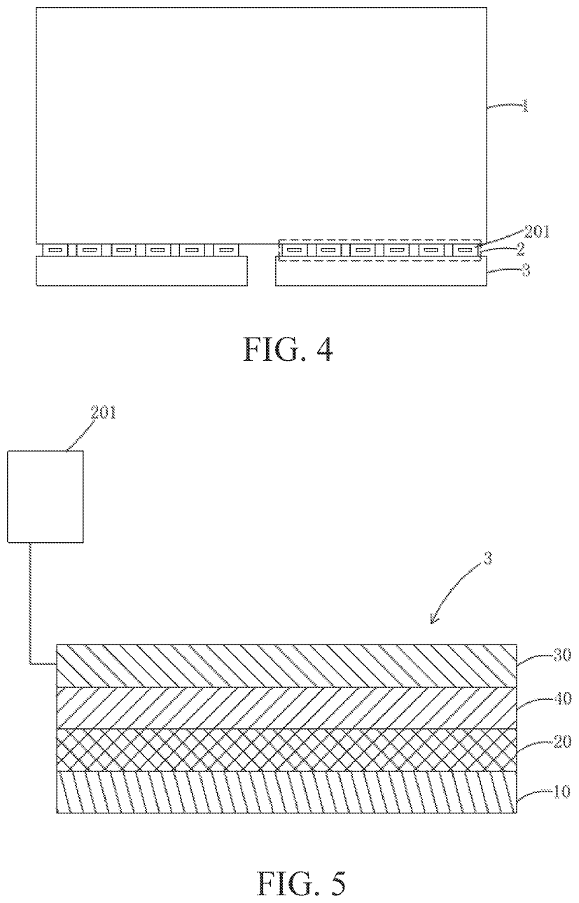

Referring to FIG. 4, based on the same inventive concept, the present invention also provides a display device comprising the above-described printed circuit board (PCB) 3.

Specifically, referring to FIG. 4, the display device comprises a display panel 1, a plurality of chip on films (COF) groups 2 electrically connected to the display panel 1, and a plurality of the above-mentioned PCBs 3 are electrically connected to the plurality of COF groups 2. Each of the PCBs 3 is electrically connected to each of the corresponding COF groups 2. Referring to FIG. 5, the third trace layer 30 of each PCB 3 is electrically connected to the COF elements 201 in the corresponding COF group 2 and transmit a driving signal to the COF elements 201 through the third trace layer 30.

It should be noted that, in conjunction with FIG. 5, in the PCB 3 of the display device of the present invention, the first trace layer 10 is disposed to comprise the GOA signal trace group 11, the data signal trace group 12, and the signal isolation trace 13 disposed on the same plane. The GOA signal trace group 11 and the data signal trace group 12 are respectively located on both sides of the signal isolation trace 13, and the reference ground layer 20 is disposed above the first trace layer 10 and above the reference ground layer 20. The third trace layer 30 is not adjacent to the GOA signal trace group 11 for transmitting the GOA circuit control signals, and the transmitted drive signals are not interfered by the GOA circuit control signals, although the reference layer 20 is adjacent to the first trace layer 10, but since the reference ground layer 20 is coupled to the reference ground potential, its potential is not interfered by the GOA circuit control signals transmitted on the GOA signal trace group 11. Furthermore, due to the first trace layer 10 comprises a GOA signal trace group 11, a data signal trace group 12, and a signal isolation trace 13 disposed on the same plane, and the GOA signal trace group 11 and the data signal trace group 12 are respectively located on both sides of the signal isolation trace 13, interferences of the GOA circuit control signals to the transmitted data signals of the data signal trace group 12 can be prevented, thereby avoiding signal interference between the trace layers in the printed circuit board, and effectively ensuring stable operation of the display device.

In summary, the printed circuit board of the present invention comprises a first trace layer, a reference ground layer disposed above and insulated from the first trace layer, and a third trace layer disposed above and insulated from the reference ground layer. The first trace layer comprises a GOA signal trace group, a data signal trace group, and a signal isolation trace disposed on the same plane, and the GOA signal trace group and the data signal trace group are respectively located on both sides of the signal isolation trace, thereby avoiding signal interference between the trace layers in the printed circuit board, and effectively ensuring stable operation of the display device. The display device of the invention can avoid signal interference between the trace layers in the printed circuit board, and effectively ensures stable operation of the display device.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A printed circuit board (PCB), comprising a first trace layer, a reference ground layer disposed above and insulated from the first trace layer, and a third trace layer disposed above and insulated from the reference round layer;
wherein the first trace layer comprises a gate over array (GOA) signal trace group, a data signal trace group, and a signal isolating trace disposed in the same plane, and the GOA signal trace group and the data signal trace group are disposed on opposite sides of the signal isolating trace.

2. The PCB of claim 1, wherein the signal isolating trace is coupled to a reference ground potential.

3. The PCB of claim 1, wherein a width of the signal isolating trace is greater than or equal 0.5 mm.

4. The PCB of claim 1, wherein the signal isolating trace is made of metal material.

5. The PCB of claim 4, wherein the signal isolating trace is made of copper.

6. The PCB of claim 1, further comprising a second trace layer disposed between and isolated from the reference ground layer and the third trace layer, and the second trace layer is configured to supply positive voltage.

7. The PCB of claim 1, wherein the GOA signal trace group is configurated to transmit GOA circuit control signals that are pulse signals.

8. The PCB of claim 7, wherein the GOA circuit control signals comprise a start signal and at least one clock signal.

9. The PCB of claim 1, wherein the reference ground layer is coupled to a reference ground potential.

10. A display device, comprising a printed circuit board (PCB);
wherein the PCB comprises a first trace layer, a reference ground layer disposed above and insulated from the first trace layer, and a third trace layer disposed above and insulated from the reference round layer;
wherein the first trace layer comprises a gate over array (GOA) signal trace group, a data signal trace group, and a signal isolating trace disposed in the same plane, and the GOA signal trace group and the data signal trace group are disposed on opposite sides of the signal isolating trace.

11. The display device of claim 10, wherein the signal isolating trace is coupled to a reference ground potential.

12. The display device of claim 10, wherein a width of the signal isolating trace is greater than or equal 0.5 mm.

13. The display device of claim 10, wherein the signal isolating trace is made of metal material.

14. The display device of claim 13, wherein the signal isolating trace is made copper.

15. The display device of claim 10, further comprising a second trace layer disposed between and isolated from the reference ground layer and the third trace layer, and the second trace layer is configured to supply positive voltage.

16. The display device of claim 10, wherein the GOA signal trace group is configurated to transmit GOA circuit control signals that are pulse signals.

17. The display device of claim 16, wherein the GOA circuit control signals comprise a start signal and at least one clock signal.

18. The display device of claim 10, wherein the reference ground layer is coupled to a reference ground potential.
